(19) United States
(12) Patent Application Publication
(10) Pub. No.: US 2022/0130619 A1
(43) Pub. Date: Apr. 28, 2022

(54) METHOD FOR MANUFACTURING ELECTROLYTIC CAPACITOR

(71) Applicant: APAQ TECHNOLOGY CO., LTD., Miaoli County (TW)

(72) Inventor: CHIEH LIN, HSINCHU COUNTY (TW)

(21) Appl. No.: 17/201,233

(22) Filed: Mar. 15, 2021

(30) Foreign Application Priority Data
Oct. 26, 2020 (TW) 109137021

(51) Int. Cl. H01G 9/028; H01G 9/15; H01G 9/00; H01G 9/042; C08G 61/12

(52) U.S. Cl. CPC H01G 9/028; H01G 9/15; C08G 2261/135; H01G 9/042; C08G 61/126; H01G 9/0036

(57) ABSTRACT

A method for manufacturing an electrolytic capacitor is provided. A crosslinking agent is applied onto a capacitor body. A solution containing a conjugated polymer is applied onto the capacitor body after applying the crosslinking agent. A part of a solvent of the solution is removed, so as to form a polymer outer layer onto the capacitor body. The capacitor body includes an electrode body, an electrode material, a dielectric layer, and a solid electrolyte. The electrode material is formed on the electrode body. A surface of the electrode material is covered by the dielectric layer. The dielectric layer is covered by the solid electrolyte. The electrode body or the solid electrolyte is formed from at least one of polythiophene having at least one sulfonic acid group and polyselenophene having at least one sulfonic acid group.

### CROSS-REFERENCE TO RELATED PATENT APPLICATION

This application claims the benefit of priority to Taiwan Patent Application No. 109137021, filed on Oct. 26, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a method for manufacturing a capacitor, and more particularly to a method for manufacturing an electrolytic capacitor.

### BACKGROUND OF THE DISCLOSURE

A commercially available solid electrolytic capacitor usually includes: a porous metal electrode, an oxide layer on a surface of the porous metal electrode, a solid electrolyte combined in a porous structure of the porous metal electrode, an electric connector, a package, and an external electrode (pin), such as a silver layer.

The solid electrolytic capacitor, for example, is prepared from a material of tantalum, aluminum, niobium, or niobium oxide. In addition, an electrons-transferred complex, pyrolusite, or polymer can also be used to prepare the solid electrolytic capacitor. The porous metal electrode has a high surface area, so that a capacitance density of the solid electrolytic capacitor can be enhanced. In other words, the solid electrolytic capacitor can have a high capacitance in a small volume.

A π-conjugated polymer has a high electrical conductivity, so that the π-conjugated polymer is suitable for being used as the solid electrolyte. The π-conjugated polymer is also called a conductive polymer or a synthesized metal. Generally, polymers have a better machinability, a lighter weight, and a higher chemically modifiable property than metals, so that an economic importance of the π-conjugated polymer has become increasingly prominent. The known π-conjugated polymer includes polypyrrole, polythiophene, polyaniline, polyacetylene, polyphenylene, and poly(p-phenylene-vinylene), among which polythiophene is particularly important. Poly(3,4-dioxyethylthiophene) is commonly applied in industry, and is also called poly(3,4-ethylenedioxothiophene). Poly(3,4-dioxyethylthiophene) has high electrical conductivity in an oxidized form.

The solid electrolytic capacitor having very low equivalent series resistance (ESR) has become essential to the technical development of the electronic field, which is due to a decrease of a voltage logic level, an increase of an integrated density, and an increase of a circulation frequency in integrated circuits. Further, low ESR reduces energy consumption, such that the solid electrolytic capacitor can be applied to mobile batteries. Therefore, efforts have been made to lower ESR of the solid electrolytic capacitor.

In the related art, a cationic polymer prepared from 3,4-dioxyethylthiophene through an oxidative polymerization is provided to form a solid electrolyte in the solid electrolytic capacitor. Poly(3,4-dioxyethylthiophene) is used to substitute for manganese dioxide or the electrons-transferred complex in the solid electrolytic capacitor due to the high electrical conductivity and the low ESR of poly(3,4-dioxyethylthiophene), so as to improve frequency properties.

In addition, a complex formed from poly(3,4-dioxyethylthiophene) and polystyrene sulfonate (PEDOT:PSS) has good electrical conductivity and low polymerization rate, and has thus been widely used. However, there are still some problems with PEDOT:PSS that need to be solved.

For example, PEDOT:PSS is generally produced through an in-situ polymerization. The PEDOT:PSS formed through the in-situ polymerization has a large particle size, such that PEDOT:PSS cannot fill into the porous metal electrode effectively. Accordingly, when a capacitor is immersed into a solution containing PEDOT:PSS, an immersion ratio of the capacitor is usually low.

Moreover, PEDOT:PSS absorbs water easily, and capacitor elements are sensitive to steam. Once steam in an environment is absorbed by PEDOT:PSS, electrical properties of the capacitor elements can be negatively influenced, or the capacitor elements may even malfunction. Therefore, when PEDOT:PSS is used as a material of the solid electrolyte, a package structure with good water-resistance is needed.

### SUMMARY OF THE DISCLOSURE

In response to the above-referenced technical inadequacies, the present disclosure provides a method for manufacturing an electrolytic capacitor.

In one aspect, the present disclosure provides a method for manufacturing an electrolytic capacitor. The method for manufacturing the electrolytic capacitor includes steps as follows. A crosslinking agent (e) is applied onto a capacitor body. A solution (a) containing a conjugated polymer (b) is applied onto the capacitor body after applying the crosslinking agent (e). A part of a solvent (d) of the solution (a) is removed so as to form a polymer outer layer onto the capacitor body. The capacitor body at least includes an electrode body having an electrode material and a dielectric layer covering a surface of the electrode material, and a solid electrolyte formed from a conductive material and completely or partially covering a surface of the dielectric layer. The crosslinking agent (e) includes: at least one of diamine, triamine, oligoamine, polymeric amine, and any derivative thereof, at least one cation and at least one amino group, at least one multivalent cation, or a compound which is able to form the multivalent cation after applying the solution (a). The electrode body or the solid electrolyte is formed from at least one of polythiophene having at least one sulfonic acid group and polyselenophene having at least one sulfonic acid group.

Therefore, by virtue of “the electrode body or the solid electrolyte being formed from at least one of polythiophene having at least one sulfonic acid group and polyselenophene having at least one sulfonic acid group”, the electrical properties of the electrolyte capacitor manufactured by the method of the present disclosure can be enhanced.

These and other aspects of the present disclosure will become apparent from the following description of the embodiment taken in conjunction with the following drawings and their captions, although variations and modifications therein may be affected without departing from the spirit and scope of the novel concepts of the disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

An object of the present disclosure is to provide a method for manufacturing an electrolytic capacitor. Through applying a crosslinking agent and then a solution containing a conjugated polymer onto a capacitor body, the electrolytic capacitor with good electrical properties can be obtained. The crosslinking agent includes at least one of diamine, triamine, oligoamine, polymeric amine, any derivative thereof, at least one cation and at least one amino group, at least onemultivalent cation, and a compound which is able to form the multivalent cation after applying the solution containing the conjugated polymer.

In the present disclosure, applying the crosslinking agent before applying the solution can improve a problem of edges and corners of the capacitor body not being covered by the conjugated polymer. In addition, there is no need to add additive agents which contain coarse solid particles. It should be noted that if the crosslinking agent is mixed with the solution before applying onto the capacitor body, i.e., the crosslinking agent and the solution are simultaneously applied onto the capacitor body, the electrolytic capacitor prepared thereby cannot have a same effect as that achieved by the electrolytic capacitor of the present disclosure.

Therefore, the present disclosure provides the method for manufacturing the electrolytic capacitor which includes steps as follows. Firstly, the crosslinking agent (e) is applied onto the capacitor body. The capacitor body at least includes an electrode body having an electrode material, a dielectric layer covering a surface of the electrode material, and a solid electrolyte completely or partially covering a surface of the dielectric layer and formed from a conductive material. Subsequently, the solution (a) containing the conjugated polymer (b) is applied onto the capacitor body after applying the crosslinking agent (e). A part of a solvent (d) of the solution (a) is removed so as to form a polymer outer layer onto the capacitor body. The method is characterized in that the crosslinking agent (e) includes at least one of diamine, triamine, oligoamine, polymeric amine, any derivative thereof, at least one cation and at least one amino group, or at least one multivalent cation. Or, the crosslinking agent (e) can form the multivalent cation after the solution (a) is applied onto. The capacitor body or the solid electrolyte is formed from at least one of polythiophene having at least one sulfonic acid group and polyselenophene having at least one sulfonic acid group.

Examples below are provided for illustration of the embodiments, and are not construed to limit the present disclosure. In the present disclosure, the electrode material is preferably a porous body with a high surface area, such as a porous sintered body or a roughened film, and is also called an electrode body in the following description.

The electrode body covered by the dielectric layer is also called an oxidized electrode body in the following description. The term “oxidized electrode body” further includes those electrode bodies covered by the dielectric layer which is not formed through an oxidation of the electrode body. The electrode body completely or partially covered by the solid electrolyte is also called the capacitor body in the following description.

A conductive layer formed from the solution (a) through the method of the present disclosure is referred to herein as the polymer outer layer.

The solution (a) at least contains a polymer whose weight average molecular weight is larger than 1000, preferably larger than 3000, more preferably larger than 10000, even more preferably larger than 20000, and most preferably larger than 50000, so that the solution (a) can be well cross-linked via the crosslinking agent (e).

The polymer having the weight average molecular weight larger than 1000 in the solution (a) is preferably the conjugated polymer (b), a polymeric anion, or an adhesive agent. Preferably, the polymeric anion acts as the polymer having weight average molecular weight larger than 1000.

The weight average molecular weight of the polymer is measured by a gel permeation chromatograph (GPC) through use of an ion exchange column (MCX column) and an appropriate eluent, and is detected by a refractive index detector (RI detector) using a signal produced from polystyrene sulfonic acid at 25° C. as a reference.

In the present disclosure, the crosslinking agent (e) preferably is at least one of: diamine, triamine, oligoamine, polymericamine, or any derivative thereof;

a compound having at least two phosphonium groups which can be a triphenylphosphonium compound, such as (2-dimentgylaminoethyl)triphenyl-phosphonium bromide, or para-xylenebis(triphenylphosphonium bromide);

a compound having a phosphonium group and at least one amino group, such as (2-dimentgylaminoethyl)triphenylphosphonium bromide or any derivative thereof;

a compound having at least two sulfonium groups, such as triaryl sulfonium group salts shown in formula (XX):

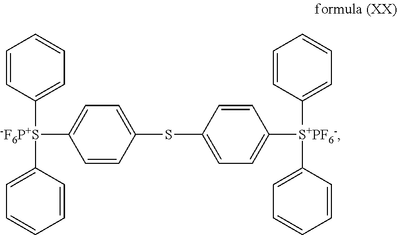

or other metals being able to form the multivalent cation, such as Mg, Al, Ca, Fe, Cr, Mn, Ba, Ti, Co, Ni, Cu, Sn, Ce, Zn, or alloys thereof.

More preferably, the crosslinking agent (e) includes at least one of diamine, triamine, oligoamine, polymericamine, any derivative thereof, and the multivalent cation.

Even more preferably, the crosslinking agent (e) includes at least one of diamine, triamine, oligoamine, polymericamine, and any derivative thereof.

Most preferably, the crosslinking agent (e) includes at least one of diamine, triamine, tetraamine, and any derivative thereof.

The oligoamine is comprehended to be compounds synthesized from at least four monomers which contain amino group, such as tetramer, pentamer, hexamer, heptamer, octamer, nonamer, decamer, undecamer, or dodecamer.

The aforesaid diamine, triamine, oligoamine, polymeric amine, and any derivative thereof have at least two amino groups. In addition, the crosslinking agent (e) can be at least one of diamine having 2 to 10 carbon atoms, triamine having 2 to 10 carbon atoms, cyclicamine having 4 to 12 carbon atoms, aromatic amine having 4 to 12 carbon atoms, and salts thereof.

Specifically, the diamine having 2 to 10 carbon atoms can be ethylenediamine, propanediamine, butanediamine, pentanediamine, hexamethylenediamine, heptanediamine, octanediamine, nonanediamine, decanediamine, tetramethylethylenediamine, tetramethylpropanediamine, tetramethylbutanediamine, tetramethylpentanediamine, tetramethylhexamethylenediamine, tetramethylheptanediamine, tetramethyloctanediamine, tetramethylnonanediamine, tetramethyldecanediamine, o-phenylenediamine, m-phenylenediamine or p-phenylenediamine. However, the present disclosure is not limited thereto. The triamine having 2 to 10 carbon atoms can be diethylenetriamine, but is not limited thereto. The cyclicamine having 4 to 12 carbon atoms can be piperazine, morpholine, piperidine, imidazole, or melamine, such as 1-(2-hydroxyethyl)piperazine, 1-(2-aminoethyl)piperazine, 4-(2-aminoethyl)morpholine, 1-(2-pyridyl)piperazine, 1-(2-aminoethyl)piperidine, 1-(3-aminopropyl)imidazole or melamine, but is not limited thereto. The aromatic amine having 4 to 12 carbon atoms can be phenyl sulfone, such as 4,4′-diaminodiphenyl sulfone, but is not limited thereto.

In the method of the present disclosure, after applying the solution (a), the crosslinking agent (e) can form the multivalent cation. Specifically, the crosslinking agent (e) reacts with the solvent (d) or other additives in the solution (a) to form the multivalent cation. For example, the crosslinking agent (e) can contain a metal. When the crosslinking agent (e) contacts the solution (a) with a pH value less than 7, the metal can form the multivalent cation. The metal, such as Ca, contained in the crosslinking agent (e) can be formed onto the capacitor body by a vapor deposition, a sputtering, sublimation, or other known processes. When the metal contacts the solution (a) with a pH value less than 7, the corresponding multivalent cation (such as Ca²⁺) can be formed. Due to the multivalent cation (Ca²⁺), the edges and corners of the capacitor body can be covered by the conjugated polymer.

Basic crosslinking agent may damage the solid electrolyte, especially when the basic crosslinking agent contains the conductive polymer. Therefore, the crosslinking agent (e) is added into a solution with a pH value (measured at 25° C.) less than 10, preferably with a pH value less than 8, more preferably with a pH value less than 7, and most preferably with a pH value less than 6. When the crosslinking agent (e) is not in a form of a solution, the pH value of the crosslinking agent (e) is measured by a pH test paper made wet by soft water.

The pH value of the solution to dissolve the crosslinking agent (e) is preferably higher than 1, much preferably higher than 2, and much more preferably higher than 3 Regarding to the aforesaid amines, the pH value of the solution can be adjusted by adding inorganic acid (such as sulfuric acid, phosphoric acid, or nitric acid) or organic acid (such as carboxylic acid or sulfonic acid). Carboxylic acid and sulfonic acid are preferred, which, for example, include aliphatic sulfonic acid having 1 to 20 carbon atoms, fluorinated aliphatic sulfonic acid, carboxylic acid having 1 to 20 carbon atoms, aliphatic perfluorocarboxylic acid, and aromatic sulfonic acid substituted by alkyl groups having 1 to 20 carbon atoms. The aliphatic sulfonic acid can be methanesulfonic acid, ethanesulfonic acid, propanesulfonic acid, butanesulfonic acid, or other advanced sulfonic acid (dodecanesulfonic acid). The fluorinated aliphatic sulfonic acid can be trifluoromethanesulfonic acid, perfluorobutanesulfonic acid, or perfluorooctanesulfonic acid. The carboxylic acid having 1 to 20 carbon atoms can be 2-ethylhexyl carboxylic acid or perfluorinated aliphatic carboxylic acid. The aliphatic perfluorocarboxylic acid can be trifluoroacetic acid or perfluorooctanoic acid. The aromatic sulfonic acid substituted by alkyl groups having 1 to 20 carbon atoms can be benzenesulfonic acid, o-toluenesulfonic acid, p-toluenesulfonic acid, dodecylbenzenesulfonic acid, or cyclic sulfonic acid (e.g., camphorsulfonic acid).

In addition to monobasic acid or monofunctional acid (e.g., monoacid, monosulfonic acid, or monocarboxylic acid), dibasic acid and ternary acid (e.g., disulfonic acid, trisulfonic acid, dicarboxylic acid, or tricarboxylic acid) can also be used to adjust the pH value.

Polymeric carboxylic acid (e.g., polyacrylic acid, polymethacrylic acid, and polymaleic acid) and polymeric sulfonic acid (e.g., polystyrene sulfonic acid and polyvinyl sulfonic acid) can also be used to adjust the pH value. The polymeric carboxylic acid and the polymeric sulfonic acid can be a copolymer polymerized form monomers of vinyl carboxylic acid, vinyl sulfonic acid, and other polymerizable monomers (e.g., acrylate and styrene).

After being applied onto the capacitor body, the crosslinking agent (e) is preferably in forms of a salt or a solution containing a salt. The crosslinking agent (e) can be used with an appropriate material (m) to form the salt, so that the crosslinking agent (e) is in the form of the salt. The appropriate material (m) can be the aforesaid acid used to adjust the pH value. In other words, the salt can be formed from the aforesaid acid and the basic crosslinking agent (e). The material (m) for use with the crosslinking agent (e) can be present in a solid, liquid, or gas state. The appropriate material (m) can also be present in a solution state with a pH value (measured at 25° C.) less than 10, preferably less than 8, much preferably less than 7, and even more preferably less than 6 In some embodiments, the crosslinking agent (e) can be applied onto the capacitor body, and then the capacitor body is treated by the solution containing the material (m) in succession. In other embodiments, the capacitor body can be previously treated by the solution containing the material (m), and then the crosslinking agent (e) is applied onto the capacitor body. In a preferable embodiment, the crosslinking agent (e) can be applied onto the capacitor body in a form of a salt, and the crosslinking agent (e) is present in a solution state with a pH value less than 10, preferably less than 8, much preferably less than 7, and much more preferably less than 6.

A solvent used for the crosslinking agent (e) can be organic solvents, such as linear or branched chain alcohols having 1 to 6 carbon atoms, cyclic alcohol having 3 to 8 carbon atoms, aliphatic ketone, aliphatic carboxylate, aromatic hydrocarbon, aliphatic hydrocarbon, chlorocarbon, aliphatic nitrile, aliphatic sulfoxide and sulfone, aliphatic carboxamide, aliphatic and aromatic ether. The linear or branched chain alcohol having 1 to 6 carbon atoms can be methanol, ethanol, isopropanol, n-propanol, n-butanol, isobutanol, or tert-butanol. The cyclic alcohol having 3 to 8 carbon atoms can be cyclohexanol. The aliphatic ketone can be acetone or methyl ethyl ketone. The aliphatic carboxylate can be ethyl acetate or butyl acetate. The aromatic hydrocarbon can be toluene or xylene. The aliphatic hydrocarbon can be hexane, heptane, or cyclohexane. The chlorocarbon can be dichloromethane or dichloroethane The aliphatic nitrile can be acetonituile. The aliphatic sulfoxide and sulfone can be dimethyl sulfoxide or sulfolane. The aliphatic carboxamide can be methylacetamide, dimethylacetamide, or dimethylformamide. The aliphatic and aromatic ether can be diethyl ether or anisole. A mixture of the aforesaid organic solvents can also be used as a solvent. Moreover, water and a mixture of water and at least one of those aforesaid organic solvents can also be used as a solvent.

Preferably, the solvent is water or other protic solvents that can be, for example, linear or branched chain alcohol having 1 to 6 carbon atoms (such as methanol, ethanol, isopropanol, n-propanol, n-butanol, isobutanol, or tert-butanol), or the cyclic alcohol having 3 to 8 carbon atoms (such as cyclohexanol). Much preferably, the solvent is a mixture of water and at least one of the aforesaid alcohols or a mixture of those aforesaid alcohols. Much more preferably, the solvent is a mixture of water and at least one of methanol, ethanol, isopropanol, and propanol.

If appropriate, the crosslinking agent (e) can also be used as a solvent. A concentration of the crosslinking agent (e) in the solvent is preferably from 0.0001 M to 10 M, more preferably from 0.001 M to 3 M, even more preferably from 0.03 M to 0.6 M, and most preferably from 0.05 M to 0.3 M.

When the crosslinking agent (e) is in a form of salt, a concentration of the crosslinking agent (e) in the solution (a) is preferably higher than 10⁻⁶ M, more preferably higher than 10⁻⁵ M, even more preferably higher than 10⁻⁴ M, and most preferably higher than 10⁻³ M.

The crosslinking agent (e) can be applied onto the capacitor body by spin coating, dipping, casting, dispensing, spraying, vapor deposition, sputtering, sublimation, knife coating, painting or printing (such as inkjet printing, screen printing or pad printing). The crosslinking agent (e) is at least applied onto the edges and/or corners of the capacitor body. In short, the crosslinking agent (e) is applied onto a complete or partial surface of the capacitor body. Further, the crosslinking agent (e) can be permeated into the porous capacitor body. After applying the crosslinking agent (e), the solvent in the crosslinking agent (e) can be partially removed through a thermal treatment. A drying temperature of the thermal treatment ranges from 15 to 500° C., preferably ranges from 25 to 300° C., and more preferably ranges from 50 to 150° C.

After applying the crosslinking agent (e) and then removing the solvent, the solution (a) containing the conjugated polymer (b) is applied onto the capacitor body. In a preferable embodiment, after applying the crosslinking agent (e) and removing the solvent, the solution (a) can be repeatedly applied onto the capacitor body, so that a thicker, a more uniform, and a denser outer layer can be formed. In other embodiments, before applying the crosslinking agent (e), the solution (a) can be applied onto the capacitor body previously.

After the step of applying the crosslinking agent (e), a part of the solution (a) contacts the capacitor body but does not remain or attach onto the capacitor body. At the same time, the solution (a) is in contact with one or more ion exchangers continuously or in phases. For example, after applying the crosslinking agent (e), the capacitor body can be immersed into the solution (a), and impurities in the solution (a) can be removed by the cation in the crosslinking agent (e), so that a crosslinking reaction can be prevented during an immersion of the capacitor body. Preferably, during the immersion of the capacitor body, the solution (a) is continuously or interruptedly processed by one or more cation exchangers. In addition, the solution (a) can further be continuously or interruptedly processed by one or more anion exchangers to further remove anions in the crosslinking agent (e). Preferably, after immersing the capacitor body, the solution (a) can be pumped through a tank containing the one or more ion exchangers continuously or in phases. For example, the one or more ion exchangers can be LEWATIT ion exchangers provided by Lanxess AG, Leverkusen, such as LEWATIT® MP 62 anion exchanger or LEWATIT® S100 cation exchanger.

An electrical conductivity of the conjugated polymer (b) in the solution (a) is higher than 10 S/cm, preferably higher than 20 S/cm, more preferably higher than 50 S/cm, even more preferably higher than 100 S/cm, and most preferably higher than 200 S/cm.

The conjugated polymer (b) is preferably contained in particles. In the method of the present disclosure, an average diameter of the particles containing the conjugated polymer (b) ranges from 1 nm to 10000 nm, preferably ranges from 1 nm to 1000 nm, and much preferably ranges from 5 nm to 500 nm.

The solution (a) preferably contains a small amount of metal and transition metal. Here, the metal should be understood as referring to metal, metal ion, or transition metal of the main group of the periodic table. The transition metal is known to damage the dielectric layer. Once the dielectric layer is damaged, a residual current enhanced by the dielectric layer can significantly reduce a service life of the capacitor, or the capacitor can no longer be operated under harsh conditions, such as high temperature and/or high humidity.

In the method of the present disclosure, an amount of metal in the solution (a) is less than 5000 mg/kg, preferably less than 1000 mg/kg, and much preferably less than 200 mg/kg. The metal refers to Na, K, Mg, Al, Ca, Fe, Cr, Mn, Co, Ni, Cu, Ru, Ce, or Zn.

In the method of the present disclosure, an amount of transition metal in the solution (a) is less than 1000 mg/kg, preferably less than 100 mg/kg, and more preferably less than 20 mg/kg. The transition metal refers to Fe, Cu, Cr, Mn, Ni, Ru, Ce, Zn, or Co.

In the method of the present disclosure, an amount of iron metal in the solution (a) is less than 1000 mg/kg, preferably less than 100 mg/kg, and much preferably less than 20 mg/kg.

When the amount of metal in the solution (a) is low enough, the dielectric layer may not be damaged during a formation of the polymer or an operation of the capacitor.

Preferably, the solution (a) at least includes a polymer used as an organic adhesive agent (c). For example, the organic adhesive agent (c) can include polyvinyl alcohol, polyvinylpyrrolidone, polyvinyl chloride, polyvinyl acetate, polyvinyl butyrate, polyacrylate, polyacrylamide, polymethacrylate, polymethacrylamide, polyacrylonitrile, benzene ethylene/acrylate, vinyl acetate/acrylate and ethylene/vinyl acetate copolymer, polybutadiene, polyisoprene, polystyrene, polyether, polyester, polycarbonate, polyurethane, polyamide, polyimide, polysulfone, melamine formaldehyde resin, epoxy resin, silicone resin or cellulose. The organic adhesive agent (c) can further include a crosslinking agent such as a melamine compound, end-capped isocyanate, functional silane (e.g., 3-glycidoxypropyltrialkoxysilane, tetraethoxysilane, and a hydrolysate of tetraethoxysilane), or a polymerizable polymer (e.g., polyurethane, polyacrylate, and polyolefin). The adhesive agent (c) can be formed from the crosslinking agent (e) and polymeric anion in the solution (a) through a reaction. The adhesive agent (c) should have good thermal stability to stand a thermal stress applied onto the capacitor at a final process, such as a welding temperature ranging from 200° C. to 260° C.

A solid content of the adhesive agent (c) in the solution (a) ranges from 0.1 wt % to 90 wt %, preferably ranges from 0.3 wt % to 30 wt %, and most preferably ranges from 0.5 wt % to 10 wt %. The solution (a) includes one or more solvents (d). For example, the solvent (d) can be aliphatic alcohol (e.g., methanol, ethanol, isopropanol, and butanol), aliphatic ketone (e.g., acetone and methyl ethyl ketone), aliphatic carboxylate (e.g., ethyl acetate and butyl acetate), aromatic hydrocarbon (e.g., toluene or xylene), aliphatic hydrocarbon (e.g., hexane, heptane, and cyclohexane), chlorocarbon (e.g., dichloromethane and dichloroethane), aliphatic nitrile (e.g., acetonituile), aliphatic sulfoxide and sulfone (e.g., dimethyl sulfoxide and sulfolane), aliphatic carboxamide (e.g., methylacetamide, dimethylacetamide, and dimethylformamide), or aliphatic and aromatic ether (e.g., diethyl ether or anisole). A mixture of the aforesaid solvents can also be used as the solvent (d). In addition, water or a mixture of water and the aforesaid solvent can also be used as the solvent (d).

Preferably, the solvent (d) is water, other protic solvents, such as alcohol (e.g., methanol, ethanol, isopropanol, butanol), or a mixture of water and the aforesaid alcohols. It is more preferable for the solvent (d) to be water.

If appropriate, the adhesive agent (c) can be used as a solvent.

The term “polymer” in the present disclosure includes a compound composed of a plurality of repeated units which can be same with or different from each other.

The conjugated polymer is a polymer having at least one double bond arranged in alternation with one single bond or a polymer having aromatic ring or heteroaryl ring arranged repeatedly.

The conductive polymer should be understood as a conjugated polymer having electrical conductivity after being oxidized or reduced. Preferably, such a conjugated polymer refers to the conductive polymer having an electrical conductivity with a magnitude of at least 1 μS/cm after being oxidized.

The conjugated polymer (b) in the solution (a) includes at least one of substituted polythiophene, substituted polypyrrole, and substituted polyaniline

Preferably, the solution (a) includes other additive agents to enhance the electrical conductivity. The additive agents can be a compound containing a ether group (e.g., tetrahydrofuran), a compound containing a lactone group (e.g., y-butyrolactone, y-valerolactone), a compound containing an amide group or a lactam group (e.g., caprolactam, N-methylcaprolactam, N,N-dimethylacetamide, N-methylacetamide, N,N-dimethylformamide (DMF), N-methyl methylformamide, N-methylformaniline, N-methylpyrrolidone (NMP), N-octylpyrrolidone, pyrrolidone), sulfone and sulfoxide (e.g., sulfolane (also called as tetramethylene sulfone) and dimethyl sulfoxide), sugar or sugar derivatives (such as sucrose, glucose, fructose, lactose, sugar alcohols (e.g., sorbitol and mannitol)), imide (e.g., succinimide and maleimide), furan derivatives (e.g., 2-furan carboxylic acid and 3-furan carboxylic acid), and/or diol or polyol (e.g., ethylene glycol, glycerin or diethylene glycol, and triethylene glycol). Preferably, the additive agent can be tetrahydrofuran, N-methylformamide, N-methylpyrrolidone, ethylene glycol, dimethylsulfoxide, or sorbitol to enhance the electrical conductivity of the solution (a). Other additives can be added into the solution (a) alone or in any combination according to various conditions.

A pH value (measured at 25° C.) of the solution (a) ranges from 1 to 14, preferably ranges from 1 to 10, and more preferably ranges from 1 to 8.

Base or acid can be added into the solution (a) to adjust the pH value of the solution (a). The base can be inorganic basic, such as sodium hydroxide, potassium hydroxide, and calcium hydroxide. The base can also be organic basic, such as ethylamine, diethylamine, triethylamine, propylamine, dipropylamine, tripropylamine, isopropylamine, diisopropylamine, butylamine, dibutylamine, tributylamine, isobutylamine, diisobutylamine, triisobutylamine, 1-methylpropylamine, methylethylamine, bis(1-methyl)propylamine, 1,1-dimethylethylamine, pentylamine, dipentylamine, 2-pentylamine, 3-pentylamine, 2-methylbutylamine, 3-methylbutylamine, bis(3-methylbutylamine), tris(3-methylbutylamine), hexylamine, octylamine, 2-ethylhexylamine, decylamine, N-methylbutylamine, N-ethylbutylamine, N,N-dimethylethylamine, N,N-dimethylpropylamine, N-ethyldiisopropylamine, allylamine, diallylamine, ethanolamine, diethanolamine, triethanolamine, methyl ethanolamine, methyldiethanolamine, dimethylethanolamine, diethylethanolamine, N-butylethanolamine, N-butyldiethanolamine, dibutylethanolamine, cyclohexylethanolamine, cyclohexyldiethanolamine, N-ethylethanolamine, N-propylethanolamine, tert-butylethanolamine, tert-butyldiethanolamine, propanolamine, dipropanolamine, tripropanolamine or benzylamine The acid can be inorganic acid (e.g., sulfuric acid, phosphoric acid, or nitric acid) or organic acid (e.g., carboxylic acid or sulfonic acid). Preferably, the additive does not destroy the liquid membrane formed by the solution (a). The additive can stand the high temperature, such as welding temperature, and remain in the solid electrolyte. For example, the base is dimethylethanolamine, diethanolamine, ammonia or triethanolamine, and the acid is polystyrene sulfonic acid.

According to various ways to apply the solution (a), a viscosity of the solution (a) measured by a rheometer at 20° C. and at a shear rate of 100 s⁻¹ ranges from 0.1 mPa·s to 100000 mPa·s, preferably ranges from 10 mPa·s to 1000 mPa·s, and most preferably ranges from 30 mPa·s to 500 mPa·s.

The electrode body or the solid electrolyte is formed from polythiophene having at least one sulfonic acid group shown in formula (I) or polyselenophene having at least one sulfonic acid group shown in formula (II).

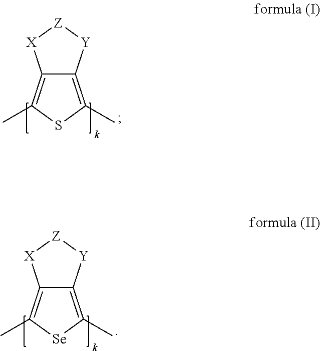

In formula (I) and formula (II), “k” is an integer ranging from 1 to 50. “X” and “Y” are respectively and independently selected from the group consisting of: an oxygen atom, a sulfur atom, and —NR¹. “R¹” is selected from the group consisting of: a hydrogen atom, a substituted or unsubstituted alkyl group having 1 to 18 carbon atoms, and a substituted or unsubstituted aromatic group having 5 to 14 carbon atoms.

The aforesaid “alkyl group having 1 to 18 carbon atoms” can be methyl, ethyl, n-propyl, isopropyl, n-butyl, isobutyl, sec-butyl, tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, or n-octyl. Preferably, R¹ is an alkyl group having 1 to 4 carbon atoms.

In formula (I) and formula (II), “Z” is —(CH₂)ₘ—CR²R³—(CH₂)ₙ—“m” is an integer ranging from 0 to 3, and “n” is an integer ranging from 0 to 3. In the present disclosure, “m is an integer ranging from 0 to 3” represents that “m” can be 0, 1, 2, or 3. “—(CH₂)—” represents a methylene group. In other words, a chain length of a substituted group “Z” changes according to values of “m” and “n”. For example, when both “m” and “n” are 0, the substituted group “Z” is —CR²R³—, so that “X”, “Z”, and “Y” in formula (I) along with the third and the fourth carbon atoms of a thiophene ring construct a pentagonal structure. When a sum of “m” and “n” is equal to 1, the substituted group “Z” is —(CH₂)—CR²R³—, so that “X”, “Z”, and “Y” in formula (I) along with the third and the fourth carbon atoms of the thiophene ring construct a hexagonal structure (shown in formula (VII) to (XII)). Similarly, “X”, “Z”, and “Y” in formula (II) along with the third and the fourth carbon atoms of a selenophene ring construct a hexagonal structure (shown in formula (XIII) to (XVIII)).

In the substituted group “Z”, “R²” is selected from the group consisting of: a hydrogen atom, —(CH₂)ₚ—O—(CH₂)_{q}—SO3⁻M⁺, —(CH₂)ₚ—NR⁴[(CH₂)_{q}—SO₃⁻M⁺], —(CH₂)ₚ—NR⁴[Ar-SO₃⁻M⁺], and —(CH₂)ₚ—O—Ar-[(CH₂)_{q}—SO₃⁻M⁺]ᵣ, “R³” is selected from the group consisting of: —(CH₂)ₚ—O—(CH₂)_{q}—SO₃⁻M⁺, —(CH₂)ₚ—NR⁴[(CH₂)_{q}—SO₃⁻M³⁰ ], —(CH₂)ₚ—NR⁴[Ar—SO₃⁻M⁺], and —(CH₂)ₚ—O—Ar—[(CH₂)_{q}—SO₃⁻M⁺]ᵣ. In addition, in each of “R²” and “R³”, “p” is an integer ranging from 0 to 6, “q” is an integer of 0 or 1, and “r” is an integer ranging from 1 to 4. “Ar” is an arylene group. “R⁴” is selected from the group consisting of: a hydrogen atom, a substituted or unsubstituted alkyl group having 1 to 18 carbon atoms, and a substituted or unsubstituted aromatic group having 5 to 14 carbon atoms. “M⁺” is a metal cation. In some embodiments, “M⁺” is a lithium ion, a sodium ion, a potassium ion, or an ammonium ion.

It should be noted that the conductive polymer of the present disclosure in formula (I) excludes poly(3,4-ethylenedioxythiophene) (PEDOT). Accordingly, the conductive polymer of the present disclosure is different from commercial conductive polymers, but can still have good electrical properties.

In a preferable embodiment, when “X” and “Y” in formula (I) and formula (II) are oxygen atoms, the polythiophene having at least one sulfonic acid group can be shown in formula (III), and the polyselenophene having at least one sulfonic acid group can be shown in formula (V). In another preferable embodiment, when “X” and “Y” in formula (I) and formula (II) include an oxygen atom and a sulfur atom, the polythiophene having at least one sulfonic acid group can be shown in formula (IV), and the polyselenophene having at least one sulfonic acid group can be shown in formula (VI).

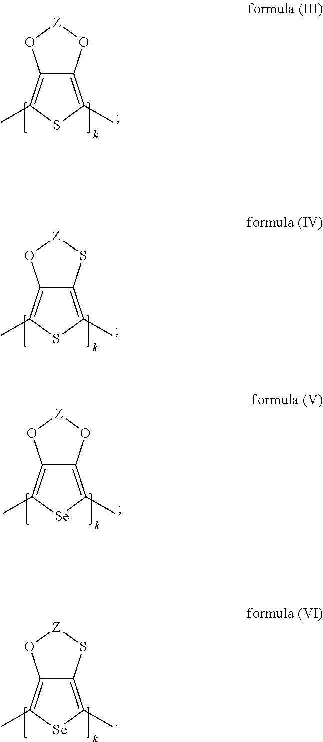

In formula (III) to formula (VI), k is an integer ranging from 1 to 50. The substituted group “Z” is —(CH₂)ₘ—CR²R³—(CH₂)ₙ—. Here, “m” is an integer ranging from 0 to 3, and “n” is an integer ranging from 0 to 3. “R²” is selected from the group consisting of: a hydrogen atom, —(CH₂)ₚ—O—(CH₂)_{q}—SO₃⁻M⁺, —(CH₂)ₚ—NR⁴[(CH₂)_{q}—SO₃⁻M⁺], —CH₂)ₚ—NR⁴[Ar—SO₃⁻M⁺], and —(CH₂)ₚ—O—Ar—[(CH₂)_{q}—SO₃⁻M⁺]ᵣ. “R³” is selected from the group consisting of: —(CH₂)ₚ—O—(CH₂)_{q}—SO₃⁻M⁺, —(CH₂)ₚ—NR⁴[(CH₂)_{q}—SO₃⁻M⁺], —(CH₂)ₚ—NR⁴[Ar—SO₃⁻M⁺], and —(CH₂)ₚ—O—Ar—[(CH₂)_{q}—SO₃⁻M⁺]ᵣ. In each of “R²” and “R³”, “p” is an integer ranging from 0 to 6, “q” is an integer of 0 or 1, and “r” is an integer ranging from 1 to 4. “Ar” is an arylene group. “R⁴” is selected from the group consisting of: a hydrogen atom, a substituted or unsubstituted alkyl group having 1 to 18 carbon atoms, and a substituted or unsubstituted aromatic group having 5 to 14 carbon atoms. “M⁺” is a metal cation. In some embodiments, “M⁺” is a lithium ion, a sodium ion, a potassium ion, or an ammonium ion.

In an embodiment, when both “X” and “Y” are oxygen atoms, and a sum of “m” and “n” is equal to 1, the polythiophene having at least one sulfonic acid group is shown in at least one of formulas (VII) to (XII), and the polyselenophene having at least one sulfonic acid group is shown in at least one of formulas (XIII) to (XVIII).

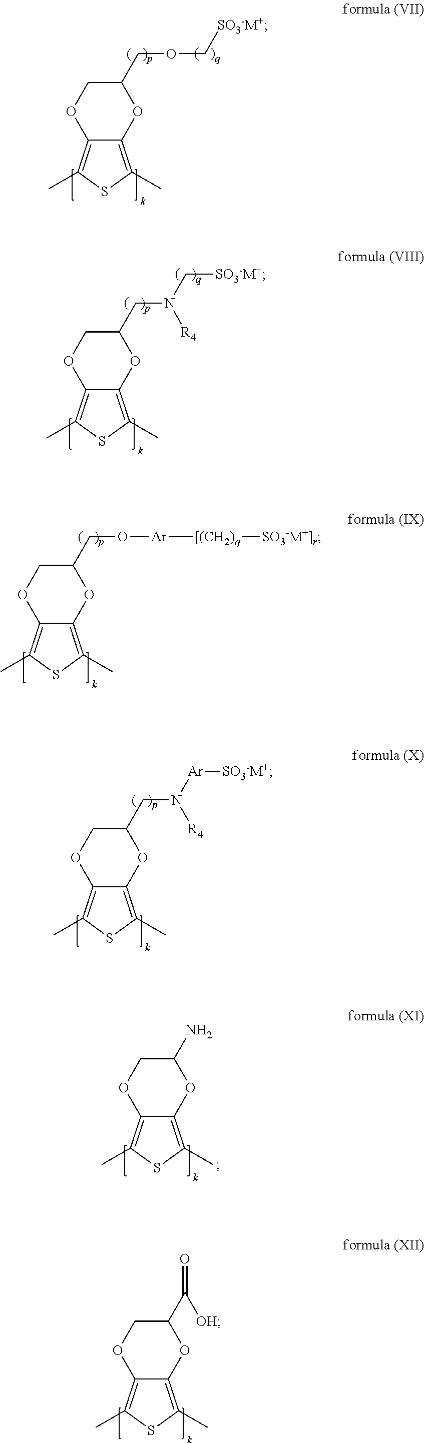

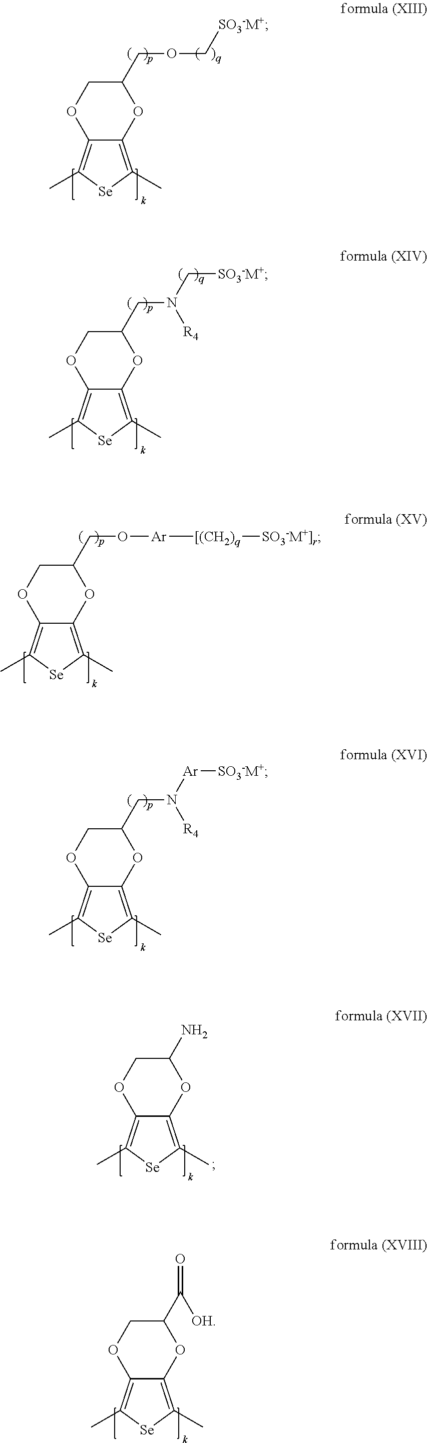

In formulas (VII) to (XVIII), k is an integer ranging from 1 to 50.

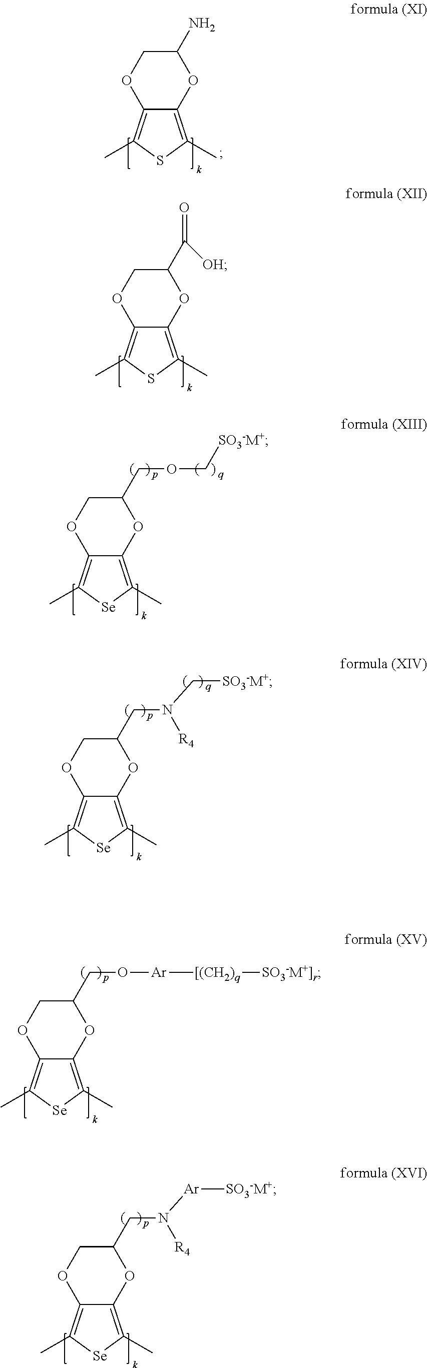

represent methylene, which is the same as “—(CH₂)—” for brevity. In each of formulas (VII) to (XVIII), “p” is an integer ranging from 0 to 6, “q” is an integer of 0 or 1, and “r” is an integer ranging from 1 to 4. “Ar” is an arylene group. “R⁴” is selected from the group consisting of: a hydrogen atom, a substituted or unsubstituted alkyl group having 1 to 18 carbon atoms, and a substituted or unsubstituted aromatic group having 5 to 14 carbon atoms. “M⁺” is a metal cation. In some embodiments, “M⁺” is a lithium ion, a sodium ion, a potassium ion, or an ammonium ion.

A thickness of the solid electrolyte formed onto the surface of the dielectric layer is thinner than 1000 nm, preferably thinner than 200 nm, and most preferably thinner than 50 nm.

A covering ratio of the solid electrolyte on the dielectric layer can be determined by measuring capacitances of the capacitor in a dry state and a wet state with a frequency of 120 Hz. The covering ratio is expressed in percentages, and is calculated by a ratio of the capacitance measured in the dry state to the capacitance measured in the wet state. The term “dry state” means that the capacitor is dried at an increasing temperature (80° C. to 120° C.) for hours before being measured. The term “wet state” means that the capacitor is exposed to a wet environment with increasing pressure (such as a steamer with saturated humidity) for hours before being measured. When the capacitor is exposed to the wet environment, moisture penetrates through holes not covered by the solid electrolyte and condenses into a liquid electrolyte.

The covering ratio of the solid electrolyte on the dielectric layer is preferably higher than 50%, much preferably higher than 70%, and most preferably higher than 80%.

When a porous membrane, such as aluminum foil, replaces the porous sintered body and is used as the electrode body, a structure similar to that mentioned previously can be formed onto the porous membrane. To achieve a high capacitance, a plurality of the porous membranes that are in contact with each other are connected in parallel and packaged together.

A thickness of the polymer outer layer preferably ranges from 1 μm to 1000 μm, more preferably ranges from 1 μm to 100 μm, even more preferably ranges from 2 μm to 50 μm, and most preferably ranges from 4 μm to 20 μm. The thickness of the polymer outer layer can change according to different parts of the capacitor body. Specifically, the thickness of the polymer outer layer on the edges of the capacitor body can be thicker or thinner than the thickness of the polymer outer layer on side surfaces of the capacitor body. However, a uniform thickness is preferred.

A multilayer system can be formed onto the capacitor body, and the polymer outer layer is a part of the multilayer system. Other functional layers can also be formed onto the polymer outer layer. In addition, a quantity of the polymer outer layer can be more than one.

Generally, the electrolyte capacitor of the present disclosure can be formed by steps as follows. For example, electron tube metal powders with a high surface area are pressed and sintered to become the porous electrode body. Further, an electrical contact wire prepared from the electron tube metal powder (such as tantalum) can also be pressed into the electrode body. Alternatively, a metal foil can be etched to obtain the porous membrane.

The dielectric layer (i.e., an oxide layer) is coated onto the electrode body through an electrochemical oxidation. The conductive polymer is deposited onto the dielectric layer through an oxidative polymerization, a chemical deposition, or an electrochemical deposition, so as to form the solid electrolyte. Specifically, precursors for the conductive polymer, one or more oxidants, and, if appropriate, counter ions are concurrently or sequentially applied onto the dielectric layer of the porous electrode body, so as to form the solid electrolyte through the chemical oxidative polymerization. In other embodiments, the precursors for the conductive polymer and the counter ions are applied onto the dielectric layer of the porous electrode body, so as to form the solid electrolyte through an electrochemical polymerization. In order to form the solid electrolyte, the conductive material is preferably a solution including substituted polythiophene, substituted polypyrrole, or substituted polyaniline

In the present disclosure, after the formation of the solid electrolyte, the solution (a) containing the conjugated polymer (b) and the solvent (d), and the crosslinking agent (e) are applied onto the capacitor body. A part of the solvent (d) is removed, so that the polymer outer layer is formed. The polymer outer layer can be post-processed to enhance the electrical conductivity of the conjugated polymer (b) in the polymer outer layer. The post-processing can be a thermal post-processing. Other functional layers can be formed onto the polymer outer layer. For example, a graphite coating layer and a silver coating layer having good electrical conductivities can be used as electrodes to discharge electric current. A plurality of the capacitor bodies in contact with each other can be connected and packaged to form the capacitor.

In a preferable method to manufacture the electrolytic capacitor, the electrode material is electron tube metal or compounds whose electrical properties are similar to the electron tube metal.

In the present disclosure, “the electron tube metal” refers to metals whose oxidized state does not allow electrical currents to flow equally in two directions. When a voltage is applied to an anode electrode, the oxide layer of the electron tube metal can block the electrical current from flowing, while a current large enough to destroy the oxide layer is generated on a cathode electrode. The electron tube metal includes Be, Mg, Al, Ge, Si, Sn, Sb, Bi, Ti, Zr, Hf, V, Nb, Ta, W, and an alloy or a compound containing at least one thereof The common electron tube metal includes Al, Ta, and Nb. The compounds having electrical properties similar to the electron tube metal have metal electrical conductivity and can be oxidized to form the oxide layer mentioned previously. For example, “NbO” has metal electrical conductivity but usually is not regarded as the electron tube metal. However, since “NbO” has typical properties of the electron tube metal, an alloy or a compound containing NbO or NbO along with other elements is a typical example of the compounds which have electrical properties similar to the electron tube metal.

The electrode material preferably contains tantalum and aluminum, or the electrode material is a niobium or niobium oxide based material.

“The niobium or niobium oxide based material” means that the niobium or niobium oxide is a major component of the electrode material. The niobium or niobium oxide based material preferably is niobium, NbO, NbOₓ, niobium nitride, niobium oxynitride, or a mixture, a compound, or an alloy thereof. “x” is a value between 0.8 and 1.2.

The alloy can include at least one electron tube metal, such as Be, Mg, Al, Ge, Si, Sn, Sb, Bi, Ti, Zr, Hf, V, Nb, Ta, or W. The term “oxidizable metal” refers to not only metal but also an alloy or a compound containing metal and other elements, as long as the oxidizable metal has the metal electrical conductivity and is able to be oxidized.

The oxidizable metal powder can be sintered to form the porous electrode body or allow a metal body to have a porous structure. The latter, for example, can be achieved by etching a membrane.

The porous electrode body can be oxidized in an appropriate electrolyte (e.g., phosphorus acid) by applying a forming voltage. A degree of the forming voltage is dependent on a thickness of the oxide layer to be formed or an applied voltage for operation of the capacitor. Preferably, the forming voltage ranges from 1 V to 800 V, and more preferably from 1 V to 300 V.

To form the porous electrode body, a specific charge of the oxidizable metal powder ranges from 1000 μC/g to 1000000 μC/g, preferably ranges from 5000 μC/g to 500000 μC/g, more preferably ranges from 5000 μC/g to 300000 μC/g, and even more preferably ranges from 10000 μC/g to 200000 μC/g.

The specific charge of the oxidizable metal powder is calculated by a formula as follows: specific charge of the oxidizable metal powder=(capacitance×anodizing voltage)/weight of the oxidized electrode body.

The capacitance of the oxidized electrode body is measured at a frequency of 120 Hz in an electrolyte containing water. The electrical conductivity of the electrolyte is high enough, so that a capacitance of the oxidized electrode body does not decrease for the resistivity of the electrolyte. For example, the capacitance of the oxidized electrode body is measured in 18% aqueous sulfuric acid being the electrolyte.

A porous ratio of the electrode body ranges from 10% to 90%, preferably ranges from 30% to 80%, and more preferably ranges from 50% to 80%.

An average aperture of the porous electrode body ranges from 10 nm to 10000 nm, preferably ranges from 50 nm to 5000 nm, and more preferably ranges from 100 nm to 3000 nm.

Therefore, the method for manufacturing the electrolyte capacitor of the present disclosure is characterized in that the electron tube metal or the compounds having properties similar to the electron tube metal includes tantalum, niobium, aluminum, titanium, zirconium, hafnium, vanadium, an alloy or a compound thereof, and NbO and an alloy or a compound containing NbO.

The dielectric layer is formed from an oxide of the electrode material and can optionally include other elements or compounds.

The capacitance of the capacitor is dependent on not only types of the dielectric layers but also a surface area and a thickness of the dielectric layer. The specific charge is an amount of the charges that can be accommodated in per unit weight of the oxidized electrode body. The specific charge is calculated by a formula as follows: specific charge of the capacitor=(capacitance×rated voltage)/weight of oxidized electrode body.

The capacitance of the final capacitor is measured at a frequency of 120 Hz. The rated voltage is a voltage by which the capacitor is to be operated. The weight of the oxidized electrode body is a total weight of the electrode body coated with the dielectric layer, exclusive of polymer, contacts, and a packaging.

A specific charge of the electrolyte capacitor manufactured by the method of the present disclosure ranges from 500 μC/g to 500000 μC/g, preferably ranges from 2500 μC/g to 250000 μC/g, more preferably ranges from 2500 μC/g to 150000 μC/g, and even more preferably ranges from 5000 μC/g to 100000 μC/g.

A solid content of the conjugated polymer (b) in the solution (a) ranges from 0.1 wt % to 90 wt %, preferably ranges from 0.5 wt % to 30 wt %, and most preferably ranges from 0.5 wt % to 10 wt %.

The solution (a) can be applied onto the capacitor body by spin coating, dipping, casting, dispensing, spraying, vapor deposition, sputtering, sublimation, knife coating, painting or printing (e.g., inkjet printing, screen printing or pad printing).

After applying the solution (a), the solvent (d) is removed so that the conjugated polymer (b) in the solution (a) and other additive agents can form the polymer outer layer. However, the solvent (d) can also partially remain in the polymer outer layer. According to various types of the solvent (d), the solvent (d) can be completely solidified or partially solidified after removing a part of the solvent (d).

The solvent (d) can be removed through evaporation at room temperature. A higher temperature can accelerate the evaporation to remove the solvent (d), such as 20° C. to 300° C., and preferably 40° C. to 250° C. A thermal treatment can be performed concurrently with the evaporation or performed after coating.

According to various types of the solution (a) for coating, the thermal treatment can continue for 5 seconds to hours. Regarding to the thermal treatment, operating temperature and resting time of a temperature curve can be adjusted according to requirements.

The thermal treatment can be performed in steps as follows. The coated oxidized electrode body passes through a heating room at a speed so as to stay at a determined temperature for a required resting time. In addition, the thermal treatment can be performed in an oven or a plurality of ovens with different temperatures.

After a formation of the polymer outer layer, layers having a good electrical conductivity can be optionally disposed onto the capacitor, such as a graphite layer and/or a silver layer, and then the capacitor can be connected to contacts and be packaged.

By the method of the present disclosure, the solid electrolyte capacitor with the polymer outer layer can be easily manufactured. Even the edges and the corners of the solid electrolyte capacitor are covered by the polymer outer layer. Therefore, the solid electrolyte capacitor of the present disclosure is outstanding for a low ESR, a low residual electrical current, and a high thermal stability. Moreover, the solid electrolyte capacitor manufactured by the method of the present disclosure is also outstanding for the low ESR, the low residual electrical current, and the high thermal stability.

Due to the properties of the low ESR and the low residual electrical current, the solid electrolyte capacitor manufactured by the method of the present disclosure can be used as elements in an electronic circuit, such as a filter capacitor or a decoupling capacitor. The purpose of the solid electrolyte capacitor is also a part of the present disclosure. Preferably, the solid electrolyte capacitor is applied in the electronic circuit, such as a computer (e.g., desktop computer, laptop computer, and computer server), peripheral devices of the computer (e.g., PC card), portable electronic devices (e.g., mobile phones, digital cameras, and entertainment electronics), devices for entertainment electronics (e.g., CD/DVD players, and computer game consoles), navigation systems, communication equipment, household appliances, power supplies, and automotive electronics.

In conclusion, by virtue of “the electrode body or the solid electrolyte being formed from at least one of polythiophene having at least one sulfonic acid group and polyselenophene having at least one sulfonic acid group”, the electrical properties of the electrolyte capacitor manufactured by the method of the present disclosure can be enhanced.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing an electrolytic capacitor, comprising:
applying a crosslinking agent (e) onto a capacitor body, wherein the crosslinking agent (e) includes at least one of diamine, triamine, oligoamine, polymeric amine, any derivative thereof, at least one cation and at least one amino group, at least one multivalent cation, or a compound which is able to form the at least one multivalent cation after applying a solution (a);
applying the solution (a) onto the capacitor body after applying the crosslinking agent (e), wherein the solution (a) contains a conjugated polymer (b); and
removing a part of a solvent (d) of the solution (a), so as to form a polymer outer layer onto the capacitor body;
wherein the capacitor body includes an electrode body, an electrode material, a dielectric layer, and a solid electrolyte; wherein the electrode material is formed on the electrode body, a surface of the electrode material is covered by the dielectric layer, a surface of the dielectric layer is completely or partially covered by the solid electrolyte, the solid electrolyte is formed from a conductive material, and the electrode body or the solid electrolyte is formed from at least one of polythiophene having at least one sulfonic acid group and polyselenophene having at least one sulfonic acid group.

2. The method according to claim 1, wherein the solution (a) includes a polymer having a weight average molecular weight greater than 1000.

3. The method according to claim 2, wherein the polymer having weight average molecular weight greater than 1000 in the solution (a) includes at least one of the conjugated polymer (b), a polymeric anion, and an adhesive agent.

4. The method according to claim 3, wherein the polymeric anion is a polymer having a carboxylate group or a sulfonate group.

5. The method according to claim 1, wherein a pH value of the solution (a) is less than 10.

6. The method according to claim 1, wherein the solution (a) includes water or at least one organic solvent.

7. The method according to claim 1, wherein the crosslinking agent (e) is a salt or a solution containing a salt.

8. The method according to claim 7, wherein the crosslinking agent (e) is dissolved or mixed in the solution (a).

9. The method according to claim 1, wherein the step of applying the crosslinking agent (e) and the step of applying the solution (a) are repeated at least once.

10. The method according to claim 1, wherein the solution (a) includes at least one of substituted polythiophene, substituted polyaniline, and substituted polypyrrole used as the conjugated polymer (b).

11. The method according to claim 1, wherein the polythiophene having at least one sulfonic acid group is shown in formula (I) and the polyselenophene having at least one sulfonic acid group is shown in formula (II); 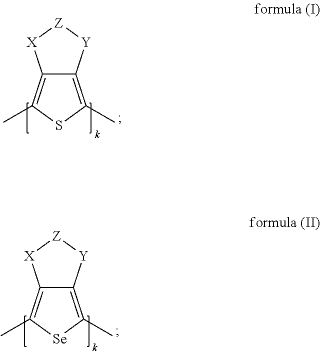
wherein X and Y are each independently selected from the group consisting of: an oxygen atom, a sulfur atom, and —NW; wherein R¹ is selected from the group consisting of: a hydrogen atom, an alkyl group having 1 to 18 carbon atoms, and an aromatic group having 5 to 14 carbon atoms; and k is an integer ranging from 1 to 50;
wherein Z is —(CH₂)ₘ—CR²R³—(CH₂)ₙ—; R² is selected from the group consisting of: a hydrogen atom, —(CH₂)ₚ—O—(CH₂)_{q}—SO₃⁻M⁺, —(CH₂)ₚ—NR⁴[(CH₂)_{q}—SO₃⁻M⁺], —(CH₂)ₚ—NR⁴[Ar—SO₃⁻M⁺], and —(CH₂)ₚ—O—Ar—[(CH₂)_{q}—SO₃⁻M³⁰ ]ᵣ; R³ is selected from the group consisting of:L —(CH₂)ₚ—O—(CH₂)_{q}—SO₃⁻M³⁰ , —(CH₂)ₚ—NR⁴[(CH₂)_{q}—SO₃⁻M³⁰ ], —(CH₂)ₚ—NR⁴[Ar—SO₃³¹ M⁺], and —(CH₂)ₚ—O—Ar—[(CH₂)_{q}—SO₃⁻M⁺]ᵣ; m is an integer ranging from 0 to 3, n is an integer ranging from 0 to 3, p is an integer ranging from 0 to 6, q is an integer of 0 or 1, r is an integer ranging from 1 to 4, and Ar is an arylene group; R⁴ is selected from the group consisting of: a hydrogen atom, a substituted or unsubstituted alkyl group having 1 to 18 carbon atoms, and a substituted or unsubstituted aromatic group having 5 to 14 carbon atoms; and M⁺ is a metal cation.

12. The method according to claim 1, wherein the polythiophene having at least one sulfonic acid group is shown in formula (III) or (IV), and the polyselenophene having at least one sulfonic acid group is shown in formula (V) or (VI); 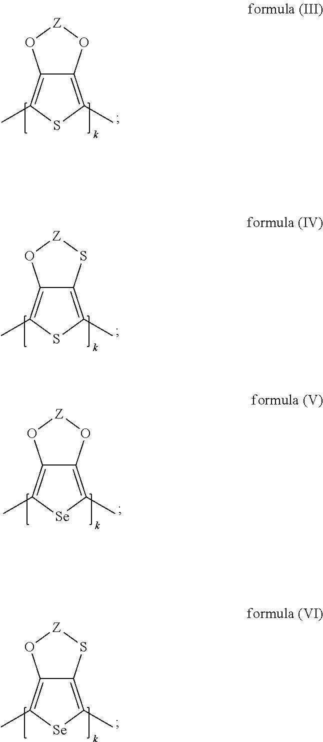 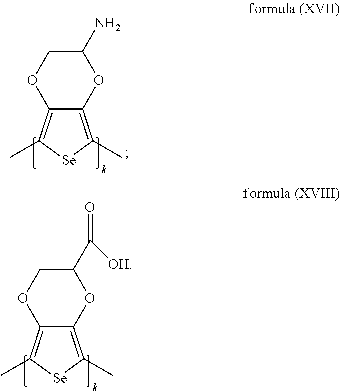
wherein k is an integer ranging from 1 to 50, and Z is —(CH₂)ₘ—CR²R³—(CH₂)ₙ—; R² is selected from the group consisting of: a hydrogen atom, —(CH₂)ₚ—O—(CH₂)_{q}—SO₃⁻M⁺, —(CH₂)ₚ—NR⁴[(CH₂)_{q}—SO₃⁻M³⁰ ], —(CH₂)ₚ—NR⁴[Ar—SO₃⁻M⁺, and —(CH₂)ₚ—O—Ar—SO₃⁻M⁺]ᵣ; R³ is selected from the group consisting of: —(CH₂)ₚ—O—(CH₂)_{q}—SO₃⁻M⁺, —(CH₂)ₚ—NR⁴[(CH₂)_{q}—SO₃³¹ M⁺], —(CH₂)ₚ—NR⁴[Ar—SO₃⁻M⁺], and —(CH₂)ₚ—O—Ar—[(CH₂(_{q}—SO₃⁻M⁺]ᵣ; m is an integer ranging from 0 to 3, n is an integer ranging from 0 to 3, is an integer ranging from 0 to 6, q is an integer of 0 or 1, r is an integer ranging from 1 to 4, and Ar is an arylene group; R⁴ is selected from the group consisting of: a hydrogen atom, a substituted or unsubstituted alkyl group having 1 to 18 carbon atoms, and a substituted or unsubstituted aromatic group having 5 to 14 carbon atoms; and M⁺ is a metal cation.

13. The method according to claim 1, wherein the polythiophene having at least one sulfonic acid group is shown in at least one of formulas (VII) to (XII), and the polyselenophene having at least one sulfonic acid group is shown in at least one of formulas (XIII) to (XVIII); 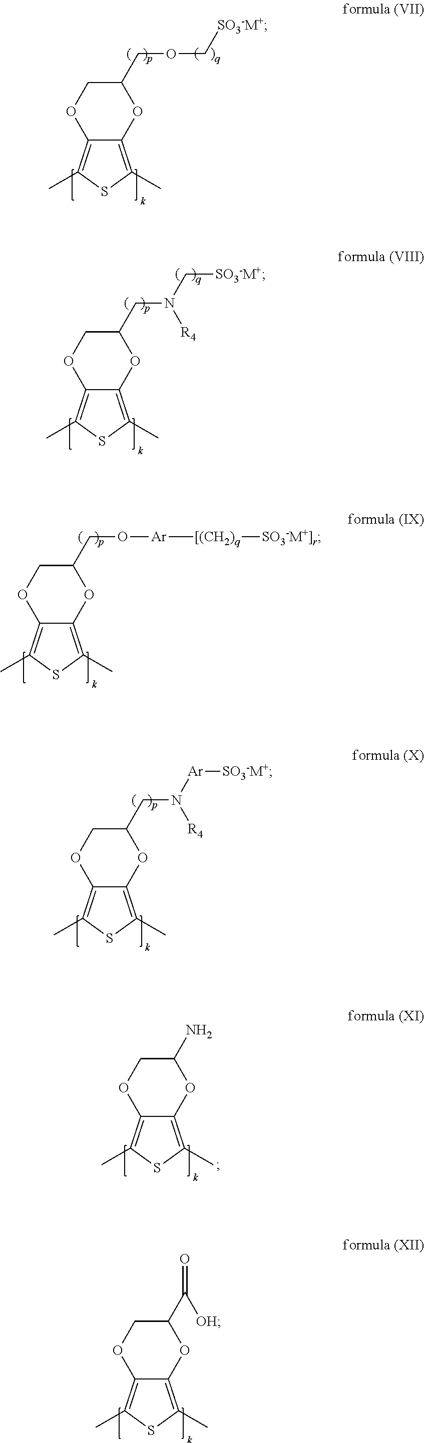 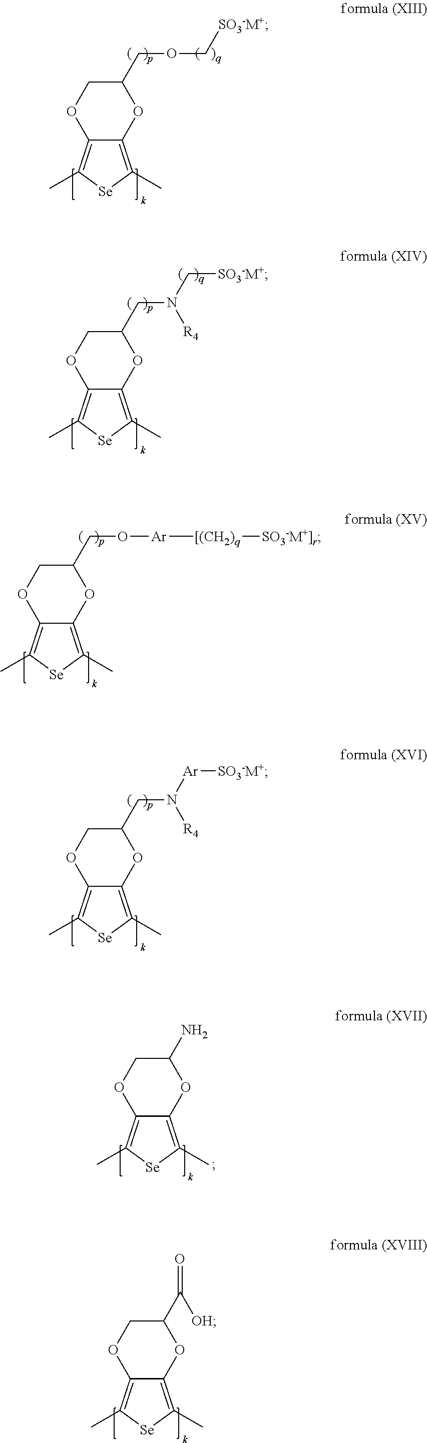
wherein Ar is an arylene group; R⁴ is selected from the group consisting of: a hydrogen atom, a substituted or unsubstituted alkyl group having 1 to 18 carbon atoms, and a substituted or unsubstituted aromatic group having 5 to 14 carbon atoms; M⁺ is a metal cation; and p is an integer ranging from 0 to 6, q is 0 or 1, r is an integer ranging from 1 to 4, and k is an integer ranging from 1 to 50.

14. The method according to claim 1, wherein the conductive material is formed from the polythiophene having at least one sulfonic acid group.
